(19) United States
(12) Patent Application Publication
(10) Pub. No.: US 2019/0105748 A1
(43) Pub. Date: Apr. 11, 2019

(54) SEAL-LESS AIRLOCK WAFER STAGE

(71) Applicant: Samsung Electronics Co., Ltd., Suwon-si (KR)

(72) Inventors: Richie LAMBE, Round Rock, TX (US); Clement HENRY, Austin, TX (US); Alexis FERNANDEZ, Cedar Park, TX (US); Anusha AYUB, Austin, TX (US)

(21) Appl. No.: 15/730,714

(22) Filed: Oct. 11, 2017

(51) Int. Cl. B23Q 11/12; H01L 21/67; C23C 14/56; C23C 14/54

(52) U.S. Cl. CPC B23Q 11/128; H01L 21/67109; H01L 21/67167; C23C 14/54; H01L 21/67173; H01L 21/67196; C23C 14/568; H01L 21/67178

(57) ABSTRACT

An airlock stage body includes a top surface, a bottom surface and a side surface. The bottom surface includes a peripheral edge that is continuous around a periphery of the bottom surface. The side surface includes a first part extending from the peripheral edge of the bottom surface to a first edge in the side surface, a second part extending from the first edge towards a center of the body to a third part extending from the second part toward the top surface. The second and third parts of the side surface may include a roughness parameter that is less than or equal to about 20 pin. At least one aperture may extend from the bottom surface to the top surface, and an insert corresponding to each aperture may be bolted to the bottom surface of the body.

### TECHNICAL FIELD

The subject matter disclosed herein generally relates to semiconductor fabrication equipment, and more particularly, to an airlock stage that is part of an ion implanter.

### BACKGROUND

During transport of a semiconductor wafer from an equipment front-end module (EFEM), which may be at atmospheric pressure, to a process chamber, such as an ion implanter that may be in a vacuum state, turbulent airflow may induce particles to move through the airlock. A seal ring that may be part of an airlock stage may tend to degrade over time, thereby releasing microscopic particles of a seal material that may contaminate a semiconductor wafer.

### SUMMARY

An example embodiment provides a body for an airlock stage that may include a top surface, a bottom surface that is opposite the top surface, and a side surface. The bottom surface may include a peripheral edge that is continuous around a periphery of the bottom surface. The side surface may be between the peripheral edge of the bottom surface and the top surface, and may include a first part extending from the peripheral edge of the bottom surface to a first edge in the side surface, a second part extending from the first edge towards a center of the body to a third part extending from the second part toward the top surface in which the second and third parts of the side surface may include a roughness that is less than or equal to about 20 pin. In one embodiment, the second and third parts of the side surface may include a roughness that is less than or equal to about 10 pin. In one embodiment, the body for an airlock stage may further include at least one aperture extending from the bottom surface to the top surface, and an insert corresponding to each aperture in which each insert may be bolted to the bottom surface of the body for the airlock stage, and a portion of each insert may extend into the corresponding aperture towards the top surface.

An example embodiment may provide a body for an airlock stage that may include a top surface, a bottom surface that is opposite the top surface, a side surface, at least one aperture and an insert corresponding to each aperture. The bottom surface may include a peripheral edge that is continuous around a periphery of the bottom surface. The side surface may be between the peripheral edge of the bottom surface and the top surface, and may include a first part extending from the peripheral edge of the bottom surface to a first edge in the side surface, a second part extending from the first edge towards a center of the body to a third part extending from the second part toward the top surface in which the second and third parts of the side surface may include a roughness that is less than or equal to about 20 pin. The at least one aperture may extend from the bottom surface to the top surface, and the insert corresponding to each aperture may be bolted to the bottom surface of the body of the airlock stage, and in which a portion of each insert may extend into the corresponding aperture towards the top surface. In one embodiment, the second part of the side surface may extend substantially horizontally and substantially perpendicularly from the first part of the side surface. In another embodiment, the third part of the side surface may extend substantially vertically and substantially perpendicularly from the second part of the side surface.

### BRIEF DESCRIPTION OF THE DRAWINGS

In the following section, the aspects of the subject matter disclosed herein will be described with reference to exemplary embodiments illustrated in the figures, in which:

FIG. 1A depicts a view of a bottom of an example embodiment of an airlock stage that may be used in a Nissen Exceed3000 AH Ion Implanter according to the subject matter disclosed herein;

FIG. 1B depicts an enlargement of an aperture for a bolted insert indicated at A in FIG. 1A;

FIG. 1C depicts a perspective of the view of the bottom of the example embodiment of the airlock stage according to the subject matter disclosed herein;

FIG. 1D depicts a cross-sectional view of the airlock stage taken along lines B-B′ in FIG. 1A;

FIG. 2A depicts a cross-sectional view of an embodiment of a conventional airlock;

FIG. 2B depicts an enlargement of a conventional threaded insert;

FIGS. 2C-2F respectively show images of a conventional threaded insert, an conventional aperture having threads within the aperture, an acrylic window being held by a user, and conventional threads within conventional apertures;

FIG. 3 shows an image of a top view of a conventional airlock stage body next to a top view of an airlock stage body according to the subject matter disclosed herein;

FIG. 4 shows an image of a bottom view of a conventional airlock stage body next to a bottom view of an airlock stage body according to the subject matter disclosed herein;

FIG. 5 shows an image of a side view of a conventional airlock stage body next to a side view of an airlock stage body according to the subject matter disclosed herein;

FIG. 6A shows an image of a closer view of a conventional threaded insert; and

FIG. 6B shows an image of a closer view of a bolted insert according to the subject matter disclosed herein.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail not to obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not be necessarily all referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. Similarly, various waveforms and timing diagrams are shown for illustrative purpose only. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing particular exemplary embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement the teachings of particular embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The subject matter disclosed herein provides a seal-less airlock stage design that is not susceptible to generate microscopic particles of a seal material that may degrade semiconductor wafers. In one embodiment, the subject matter disclosed herein provides an improved airlock stage for use in a Nissen Exceed3000 AH ion implanter that significantly reduces particle accumulation on semiconductor wafers that are being processed. The conventional airlock stage design of the Exceed3000 AH includes a separate seal ring between a main airlock stage body and an upper airlock chamber to establish a vacuum seal between the airlock stage and the airlock chamber. The sealing ring was intended to prevent particle generation caused by metal of the wafer stage colliding with metal of the airlock chamber body. Nevertheless, over time and through wear, the sealing ring tends to generate particles that may contaminate semiconductor wafers being processed.

Embodiments disclosed herein have eliminated the seal ring, thereby significantly reducing the amount of particles that may be generated that may contaminate semiconductor wafers. Additionally, eliminating the seal ring reduces cost and maintenance by a simplifying the stage design from originally having two components (i.e., a stage body and a seal ring) to having only a stage body. Another advantage provided by embodiments disclosed herein is the elimination of one of the two O-rings between the original seal ring and the original airlock stage body, which also further reduces maintenance cost and time. Still another advantage provided by embodiments disclosed herein is the elimination of a plurality of conventional stainless-steel threaded inserts that are used to secure a wafer sense window in position. The conventional threaded inserts cause particles to be released from metal shavings formed from the threads of the insert. In some instances, the sense windows may be crushed by the conventional threaded insert, causing more particles to be generated. In embodiments disclosed herein, improved sense window inserts are bolted to the airlock stage, which significantly reduces particle generation.

Airlock stage embodiments disclosed herein do not make contact with an airlock chamber, and any potential rubbing of the two metallic surfaces does not occur by design. Airlock stage body embodiments disclosed herein only make contact with an airlock chamber body O-ring.

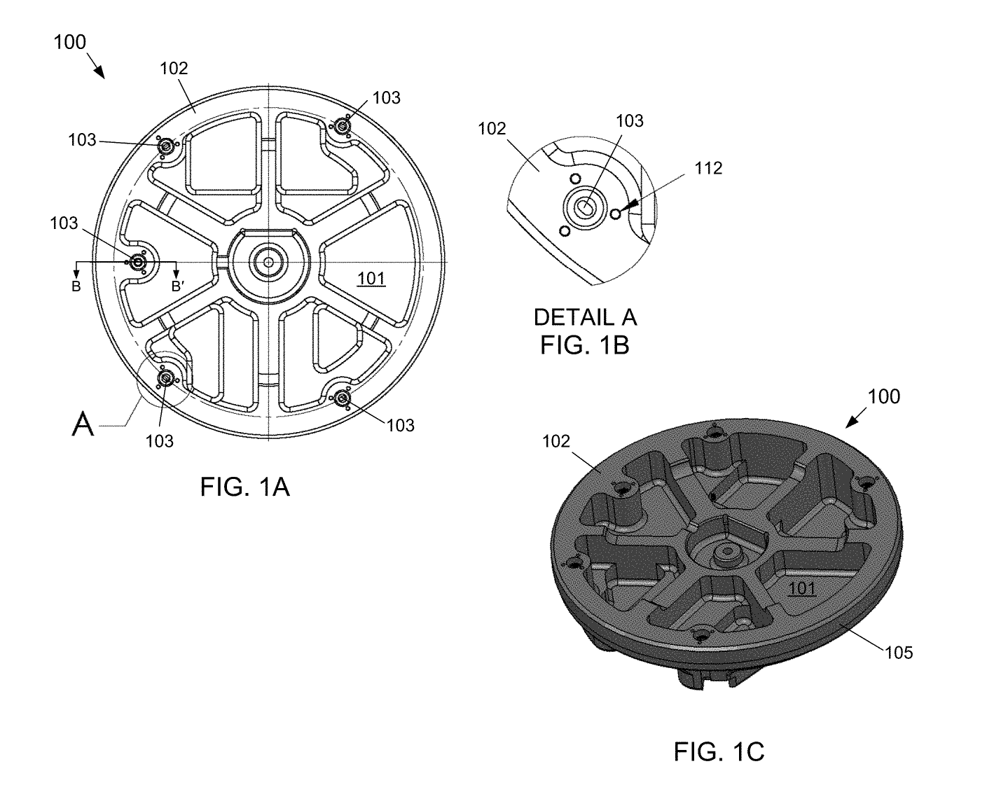

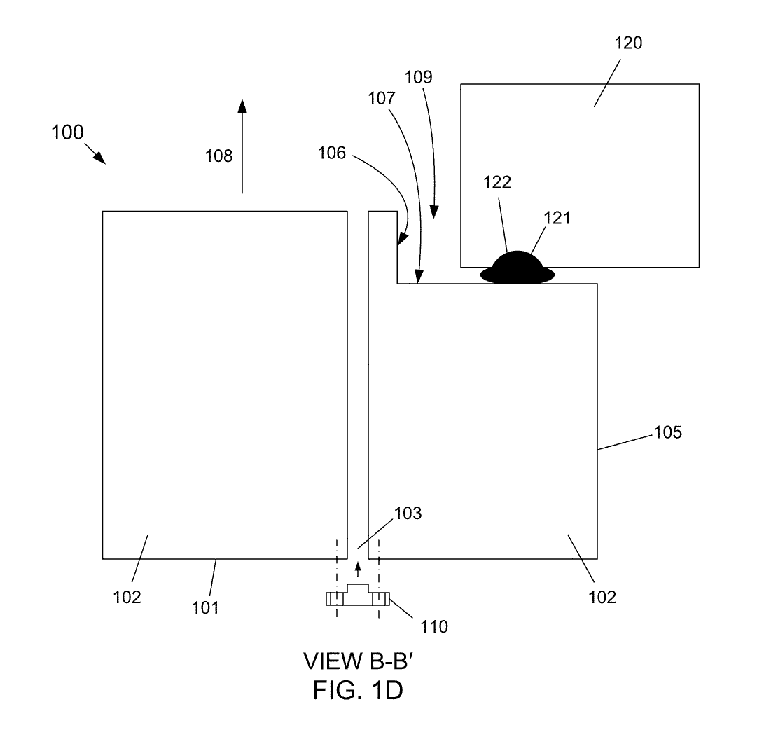

FIG. 1A depicts a view of a bottom 101 of an example embodiment of an airlock stage 100 that may be used in a Nissen Exceed3000 AH ion implanter according to the subject matter disclosed herein. FIG. 1B depicts an enlargement of an aperture for a bolted insert indicated at A in FIG. 1A. FIG. 1C depicts a perspective of the view of the bottom 101 of the example embodiment of the airlock stage 100. FIG. 1D depicts a cross-sectional view of the airlock stage 100 taken along lines B-B′ in FIG. 1A.

The airlock stage 100 may include a stage body 102 and a plurality of apertures 103 for bolted inserts. The stage body 102 may be formed from aluminum or a similar type of metal. In another embodiment, the stage body 102 may be formed from a metal having sufficient strength to prevent deflection and/or bending of the stage body 102. The apertures 103 may be used to provide a visible path for, for example, a laser vision system, to sense the status of a positioning or a condition of a wafer on the airlock stage 100. An image of an example embodiment of a bolted insert 110 is depicted in FIG. 6B. The bolted inserted 110 may be fastened to the stage body 102 using bolts 111 (FIG. 6B) that are threaded into threaded apertures 112 (FIG. 1B).

The airlock stage 100 may be used to process semiconductor wafers (not shown), which may be positioned on a top side (not shown) of the airlock stage 100. The airlock stage 100 may be used to transport semiconductor wafers from an equipment front-end module (EFEM), which may be at atmospheric pressure, to a process chamber, such as an ion implanter, that may be in a vacuum state. The robotic mechanism that moves the airlock stage 100 in order to transport the semiconductor wafers is not shown.

FIG. 1D is oriented so that the bottom 101 of the airlock stage body 102 is depicted towards the bottom of FIG. 1D, and so a side 105 of the airlock stage body 102 is depicted towards the right of FIG. 1D. The stage body 102 of the airlock stage 100 includes a substantially vertical wall 106 and a substantially horizontal O-ring surface 107. When the airlock stage 100 is moved in the direction of arrow 108 to position a semiconductor wafer (not shown) in an airlock chamber, the vertical wall 106 and the O-ring surface 107 of the body 102 are located in close proximity to a wall portion 120 of the airlock chamber. A spacing 109 between the vertical wall 106 and the wall portion 120 of the airlock chamber may be exaggerated for clarity of FIG. 1D. In one embodiment, the spacing 109 may be greater than or equal to 5 mm. As the airlock stage 100 moves towards the wall portion 120 of the airlock chamber, the O-ring surface 107 contacts an O-ring 121 that is in a groove 122 of the wall portion 120 and compresses the O-ring 121, as depicted in FIG. 1D. Contact of the O-ring surface 107 with the O-ring 121 enhances the sealing capability of the airlock stage 100 against the wall portion 120 of the airlock chamber.

The vertical wall 106 and the O-ring surface 107 of the airlock stage 100 may be machined to be very smooth by using, for example, electropolishing, also referred to as electrochemical polishing. In one embodiment, the vertical wall 106 may have a surface finish having a roughness that is less than or equal to about 20 pin. In another embodiment, the vertical wall 106 may have a surface finish having a roughness that is less than or equal to about 10 pin. In one embodiment, the O-ring surface 107 may have a surface finish having a roughness that is less than or equal to about 20 pin. In another embodiment, the horizontal surface 107 may have a surface finish having a roughness that is less than or equal to about 10 pin.

The electropolished vertical wall 105 and the O-ring surface 107 provide significantly reduced stiction and accumulation of particles on the O-ring 104. Additionally, the electropolished O-ring surface 107 significantly reduces the occurrence of the O-ring 104 rolling and prevents leaks by rotating the seam of the O-ring 104 to the sealing surface, which tends to generate particles and compromise the integrity of the vacuum of the process chamber.

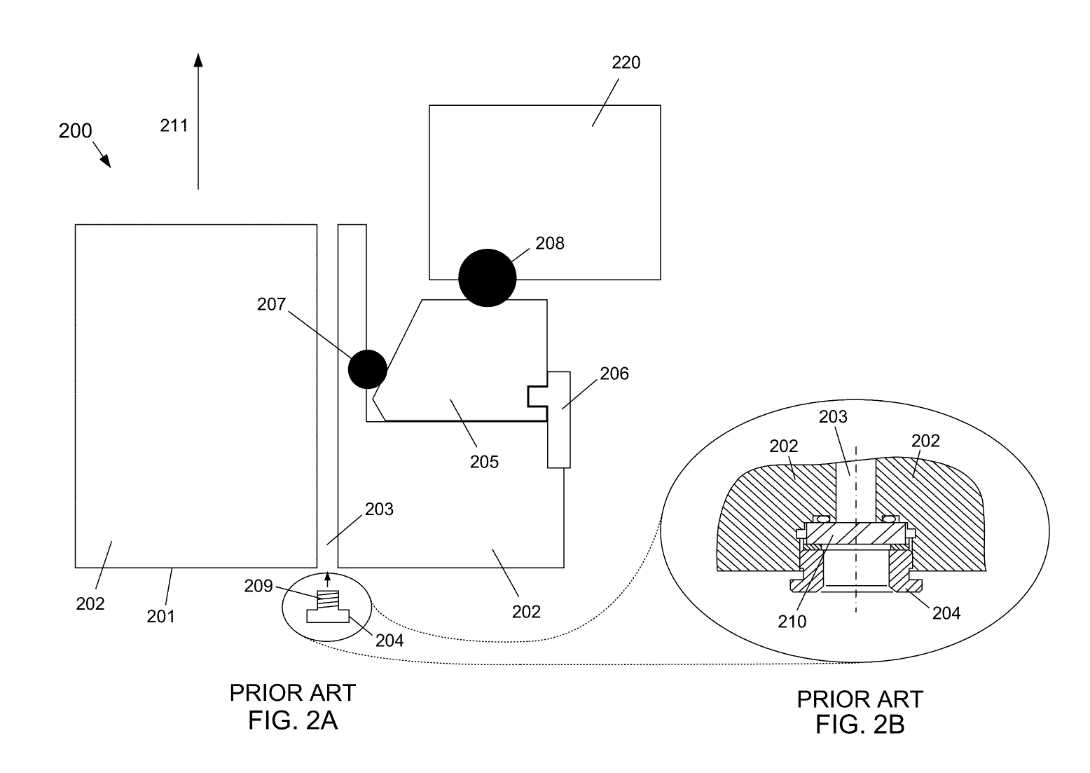

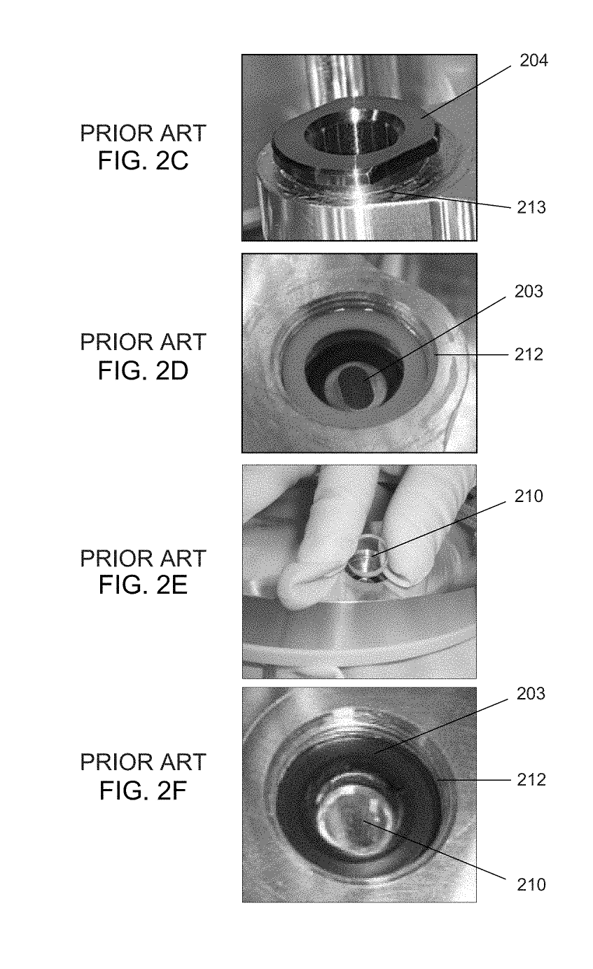

In contrast to the airlock stage 100, FIG. 2A depicts a cross-sectional view of an embodiment of a conventional airlock 200. The bottom of the conventional airlock 200 is indicated at 201. The conventional airlock 200 includes a stage body 202, a plurality of apertures 203 for threaded inserts 204, a seal ring 205, a plurality of clips 206, a first O-ring 207 and a second O-ring 208. It should be understood that only one aperture 203, only one threaded insert 204, and only one clip 206 are depicted in FIG. 2A. The apertures 203 may be used to provide a visible path to view (via, for example, a laser vision system) the positioning status or condition of a wafer on the conventional airlock stage 200. An enlargement of a conventional threaded insert 204 is depicted in FIG. 2B. Threads 209 on the threaded insert 204 are threaded into an aperture 203 and hold an acrylic window 210 (FIG. 2B) in place.

The seal ring 205 may be formed from a Teflon-based material and is held in place on the conventional airlock stage 200 by the plurality of clips 206.

When the conventional airlock stage 200 is moved in the direction of arrow 211 to position a semiconductor wafer (not shown) in an airlock chamber, the seal ring 205 experiences a compressive force as it and the O-ring 208 are pressed against a wall portion 220 of the airlock chamber. The compressive force may cause the clips 206 to slightly move, which over time causes wear on the seal ring 205 and on the clips 206 and, which in turn, may cause particles to be generated by both the seal ring 205 and the clips 206. Additionally, there is a frictional force applied to the O-ring 207, which may further generate more particles through wear of the O-ring 207 over time. Additionally, a groove into which the O-ring 207 fits area and the area around the groove and the O-ring 207 may trap and hold particles that may be eventually released. Further, the O-ring 207 may roll due to friction and cause vacuum leaks. Referring back to FIG. 1D, embodiments disclosed herein also eliminate the O-ring 207, thereby eliminating any particles that may be generated by such an O-ring.

The threaded inserts 204 may also generate particles. The threaded design of the threaded inserts 204 may be subject to overtightening, which may cause a window 210 to be crushed (thereby generating particles) and/or may weaken the threads of the insert 204 and the threads in the aperture 203 (also thereby generating particles).

FIGS. 2C-2F respectively show images of a conventional threaded insert 204; a conventional aperture 203 having threads 212 within the aperture 203; an acrylic window 210 being held by a user; and conventional threads 212 within a conventional aperture 203. Damage to the body of a conventional airlock stage 200 that may generate particles may be seen at 213 in FIG. 2C. An acrylic window 210 may be seen in place in aperture 203 in FIG. 2F.

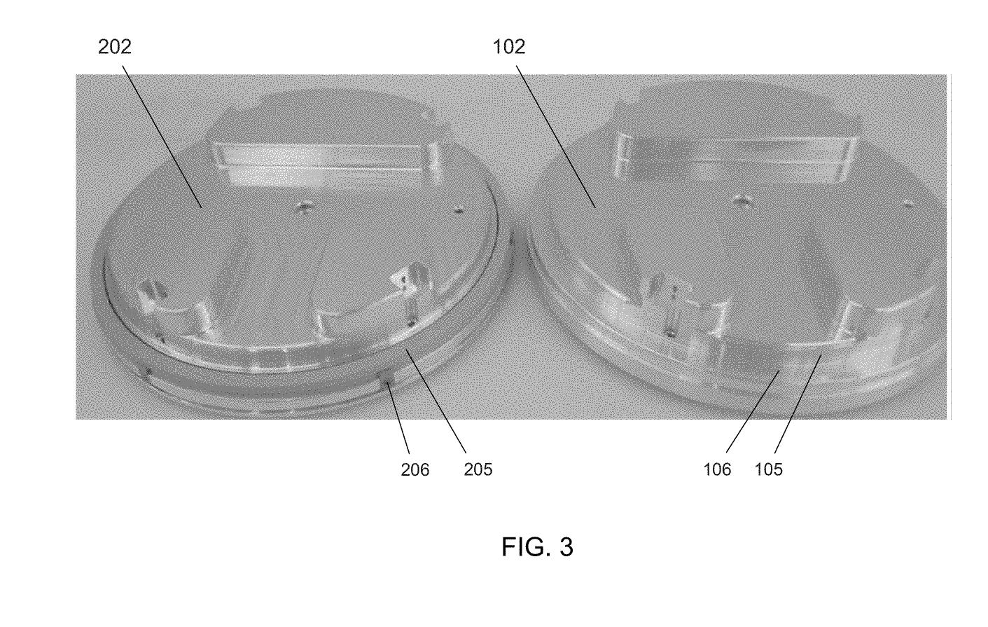

FIG. 3 shows an image of a top view of a conventional airlock stage body 202 next to a top view of an airlock stage body 102 according to the subject matter disclosed herein. The conventional airlock stage body 202 includes a conventional seal ring 205 and conventional clips 206 that tend to generate particles. In contrast, the airlock stage body 102 includes a vertical wall 106 and an O-ring surface 107 that tend not to generate particles.

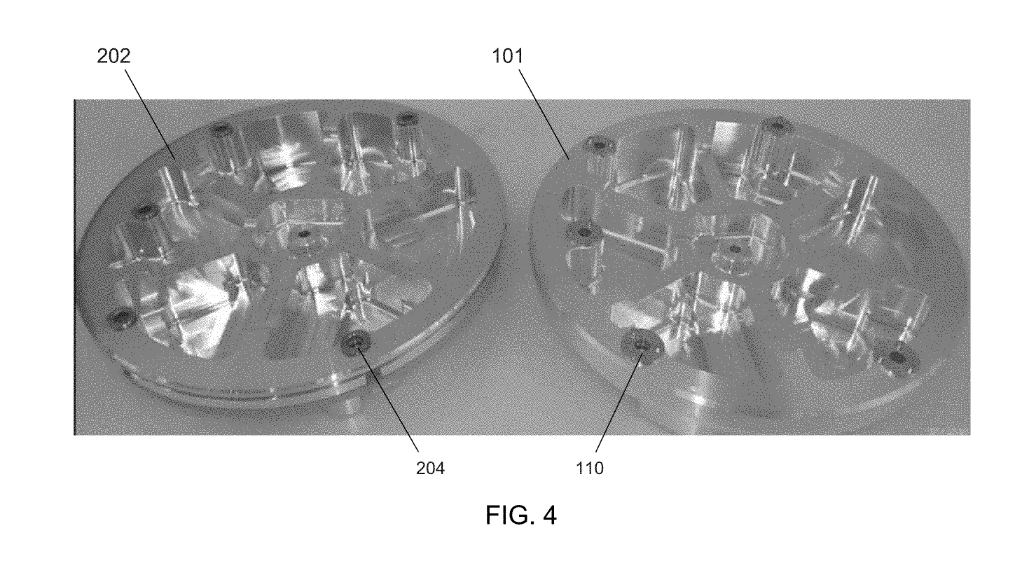

FIG. 4 shows an image of a bottom view of a conventional airlock stage body 202 next to a bottom view of an airlock stage body 102 according to the subject matter disclosed herein. The particle-generating threaded inserts 204 may be seen threaded into apertures (not shown) in the conventional airlock stage body 202. In contrast, bolted inserts 110 may be seen bolted to the airlock stage body 102.

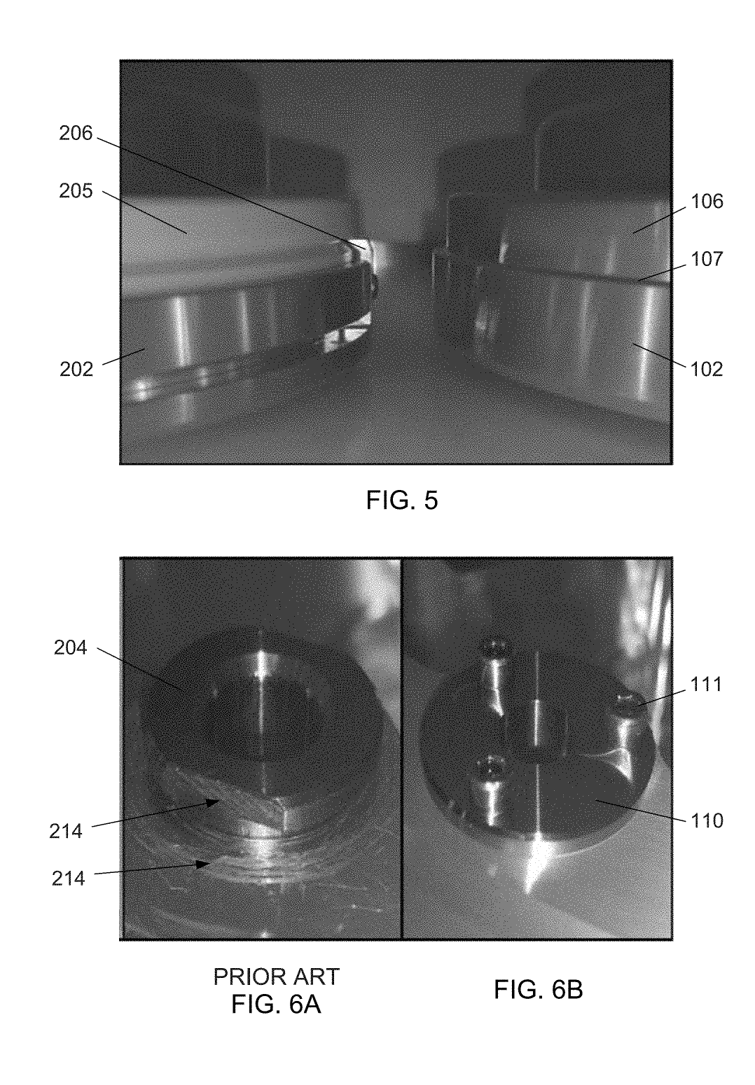

FIG. 5 shows an image of a side view of a conventional airlock stage body 202 next to a side view of an airlock stage body 102 according to the subject matter disclosed herein. The conventional airlock stage body 202 includes a conventional seal ring 205 and conventional clips 206 that tend to generate particles. In contrast, the airlock stage body 102 includes a vertical wall 106 and an O-ring surface 107 that tend not to generate particles.

FIG. 6A shows an image of a closer view of a conventional threaded insert 204. Particle-generating damage caused by a user may be seen at 214. FIG. 6B shows an image of a closer view of a bolted insert 110 according to the subject matter disclosed herein.

As will be recognized by those skilled in the art, the innovative concepts described herein can be modified and varied over a wide range of applications. Accordingly, the scope of claimed subject matter should not be limited to any of the specific exemplary teachings discussed above, but is instead defined by the following claims.

What is claimed is:

1. A body for an airlock stage, the body comprising:
a top surface;
a bottom surface opposite the top surface, the bottom surface comprising a peripheral edge that is continuous around a periphery of the bottom surface; and
a side surface between the peripheral edge of the bottom surface and the top surface, the side surface comprising a first part extending from the peripheral edge of the bottom surface to a first edge in the side surface, a second part extending from the first edge towards a center of the body to a third part extending from the second part toward the top surface, the second and third parts of the side surface comprising a roughness that is less than or equal to about 20 pin.

2. The body for an airlock stage according to claim 1, wherein the second and third parts of the side surface comprising a roughness that is less than or equal to about 10 pin.

3. The body for an airlock stage according to claim 1, further comprising:
at least one aperture extending from the bottom surface to the top surface; and
an insert corresponding to each aperture, each insert being bolted to the bottom surface of the body for the airlock stage, and a portion of each insert extending into the corresponding aperture towards the top surface.

4. The body for an airlock stage according to claim 1, wherein the second part of the side surface extends substantially horizontally and substantially perpendicularly from the first part of the side surface.

5. The body for an airlock stage according to claim 4, wherein the third part of the side surface extends substantially vertically and substantially perpendicularly from the second part of the side surface.

6. The body for an airlock stage according to claim 5, wherein the body comprises aluminum.

7. The body for an airlock stage according to claim 5, wherein the top surface is adapted to receive a semiconductor wafer.

8. A body for an airlock stage, the body comprising:
a top surface;
a bottom surface opposite the top surface, the bottom surface comprising a peripheral edge that is continuous around a periphery of the bottom surface;
a side surface between the peripheral edge of the bottom surface and the top surface, the side surface comprising a first part extending from the peripheral edge of the bottom surface to a first edge in the side surface, a second part extending from the first edge towards a center of the body to a third part extending from the second part toward the top surface, the second and third parts of the side surface comprising a roughness that is less than or equal to about 20 pin;
at least one aperture extending from the bottom surface to the top surface; and
an insert corresponding to each aperture, each insert being bolted to the bottom surface of the body of the airlock stage, and a portion of each insert extending into the corresponding aperture towards the top surface.

9. The body for an airlock stage according to claim 8, wherein the second and third parts of the side surface comprising a roughness that is less than or equal to about 10 pin.

10. The body for an airlock stage according to claim 8, wherein the second part of the side surface extends substantially horizontally and substantially perpendicularly from the first part of the side surface.

11. The body for an airlock stage according to claim 10, wherein the third part of the side surface extends substantially vertically and substantially perpendicularly from the second part of the side surface.

12. The body for an airlock stage according to claim 11, wherein the body comprises aluminum.

13. The body for an airlock stage according to claim 11, wherein the top surface is adapted to receive a semiconductor wafer.
